(19) United States
(12) Patent Application Publication
(10) Pub. No.: US 2006/0151801 A1
(43) Pub. Date: Jul. 13, 2006

(54) Light emitting diode with thermo-electric cooler

(76) Inventors: Trung Tri Doan, Los Gatos, CA (US); Chuong Anh Tran, Orange, CA (US)

Correspondence Address: LEWIS L. LOCKWOOD;LEWIS AND ROCA LLP, 40 NORTH CENTRAL AVENUE, PHOENIX, AZ, 85004, US

(21) Appl. No.: 11/032,856

(22) Filed: Jan. 11, 2005

(51) Int. Cl. H01L 23/34; H01L 21/50

(52) U.S. Cl. 257/99; 438/122; 438/26; 257/712

(57) ABSTRACT

Systems and methods for fabricating a light emitting diode include depositing one or more metal layers on a substrate; forming an n-gallium nitride (n-GaN) layer above the metal layer; and depositing a thermoelectric cooler in the metal layer to dissipate heat.

The present invention generally relates to a light-emitting diode and a method for fabricating the same.

Light-emitting diodes (LEDs) are playing an increasingly important role in our daily life. Traditionally, LEDs are become ubiquitous in many applications, such as communications and other areas, such as mobile phones, appliances and other electronic devices. Recently, the demand for nitride based semiconductor materials (e.g., having Gallium Nitride or GaN) for opto-electronics has increased dramatically for applications such as video displays, optical storage, lighting, medical instruments, for-example. Conventional blue light-emitting diodes (LEDs) are formed using semiconductor materials of nitride, such as GaN, Al GaN, InGaN and AlInGaN. Most of the semiconductor layers of the aforementioned-typed light emitting devices are epitaxially formed on electrically non-conductive sapphire substrates. Since the sapphire substrate is an electrically insulator, electrodes cannot be directly formed on the sapphire substrate to drive currents through the LEDs. Rather, the electrodes directly contact a p-typed semiconductor layer and an n-typed semiconductor layer individually, so as to complete the fabrication of the LED devices. However such configuration of electrodes and electrically non-conductive nature of sapphire substrate represents a significant limitation for the device operation. For example, a semi-transparent contact needs to be formed on the p-layer to spread out the current from p-electrode to n-electrode. This semi-transparent contact reduces the light intensity emitted from the device due to internal reflectance and absorption. Moreover, p and n-electrodes obstruct the light and reduce the area of light emitting from the device. Additionally, the sapphire substrate is a heat insulator (or a thermal insulator) and the heat generated during the device operation can not be effectively dissipated, thus limiting the device reliability. Thus, limitations of conventional LED structures include: (1) Semi-transparent contact on p-layer 5 is not 100% transparent and can block the light emitted from layer 4; (2) current spreading from n-electrode to p-electrode is not uniform due to position of electrodes; and (3) heat is accumulated during device operation since sapphire is a thermal and electrical insulator.

### SUMMARY

Systems and methods for fabricating a light emitting diode include depositing one or more metal layers on a substrate; forming an n-gallium nitride (n-GaN) layer above the metal layer; and depositing a thermoelectric cooler in the metal layer to dissipate heat.

Implementations of the above aspect may include one or more of the following. The carrier substrate can be sapphire. The deposition of the metal layer does not involve bonding or gluing the metal layer to a structure on the substrate. The depositing of the metal layer can apply using Electro chemical deposition, electroless chemical deposition, CVD chemical vapor deposition, MOCVD Metal Organic CVD, PECVD Plasma enhance CVD, ALD Atomic layer deposition, PVD Physical vapor deposition, evaporation, or plasma spray, or the combination of these techniques. The metal layer can be single or multi-layered. In case that the metal layer is a multi-layer, a plurality of metal layers with different composition can be formed and the layers could be deposited using different techniques. In embodiment, the thickest layer is deposited using electro or electroless chemical deposition

In another aspect, a method for fabricating a light emitting diode includes providing a carrier substrate; depositing a multilayer epitaxial structure; depositing one or more metal layers above the multilayer epitaxial structure; defining one or more mesas using etching; forming one or more non-conductive layers; removing a portion of the non conductive layers; depositing at least one or more metal layers; removing the carrier substrate.

Implementations of the above aspect can include one or more of the following. The metal layers could have same or different composition and deposited using various deposition techniques. The carrier substrate removal can be done using laser, etching, grinding/lapping or chemical mechanical polishing or wet etching, among others. The carrier substrate can be sapphire, silicon carbide, silicon or gallium arsenide. The multi layer epitaxial structure can be a n-type GaN layer, one or more quantum wells with InGaN/GaN layers, and a p-type GaN layer. The one or more metal layers above the multi layer epitaxial structure can be Indium Tin Oxide (ITO), Ag, Al, Cr, Ni, Au, Ti, Ta, TiN, TaN, Mo, W, a refractory metal, or a metal alloy, or a composite. An optional doped semiconductor layer can be formed between the multi layer epitaxial structure and the metal layers. The mesa can be defined using a polymer (for example: resist) or a hard mask (for example: SiO2, Si3N4, Aluminum). The non-conductive layer can be SiO₂, Si₃N₄, a diamond element, a non-conducting metal oxide element or a ceramic element or a composite of these materials; The non-conductive layer could be a single layer or could have a plurality of non-conductive layers (for example: SiO2 on Si3N4). In one implementation, the non-conductive layer is the sidewall layer or passivation layer. A portion of the non conductive layer can be removed by lifting off or dry etching to expose a conductor layer with or without using a masking layer. The conductor layer can be one or more metal layers. The one or more metal layers can be deposited using sputtering, physical vapor deposition (PVD), chemical vapor deposition (CVD), plasma enhanced CVD (PECVD), evaporation-ion beam deposition, electro deposition, electroless deposition, plasma spray, or ink jet deposition. The metal layer can include chromium (Cr), nickel (Ni), Copper on tantalum nitride (Cu/TaN), molybdenum (Mo), tungsten (W) or a metal alloy. One or more of the additional metal layers can be formed by electro plating or electroless plating. The additional metal layer can be copper (Cu), nickel (Ni), gold (Au), aluminum (Al), or an alloy thereof. A conductive passivation layer can be deposited, and can be a metal, nickel (Ni), chromium (Cr), or zinc (Zn).

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others.

In another method for fabricating a light emitting diode, the process includes providing carrier substrate; depositing a multilayer epitaxial structure; depositing one or more metal layers above the multilayer epitaxial structure; etching one or more mesas; forming one or more non conductive layers; removing a portion of the non conductive layers; depositing one or more metal layers and forming heat removal device thereon; removing the carrier substrate.

Implementations of the above method may include one or more of the following. The metal layers could have same or different composition and deposited using various deposition techniques. The carrier substrate removal can be done using laser, etching, grinding/lapping or chemical mechanical polishing or wet etching, among others. The carrier substrate can be sapphire. The depositing the metal layer can be electro deposition or electroless deposition. The depositing the metal layer can include CVD, PECVD, PVD, evaporation, or plasma spray. Electrodes can be placed on the multilayer structure. One or more additional metal layers can be formed above the original metal layer.

In a further aspect, a method for fabricating a light emitting diode includes forming a multi layer epitaxial structure above a substrate (such as a sapphire substrate, for example), depositing a metal layer above the epitaxial layer (using electro or electroless plating), and removing the substrate (using laser lift-off technique, for example).

In one implementation, the multi-layer epitaxial structure includes a reflective metal layer coupled to the metal plating layer; a passivation layer coupled to the reflective metal layer; a p-GaN layer coupled to the passivation layer; a multi-quantum well (MQW) layer coupled to the p-GaN layer; a n-GaN layer coupled to the MQW layer; an n-electrode coupled to the n-GaN layer.

The metal layer can be single or multi-layered. In case that the metal layer is a multi-layer, a plurality of metal layers with different composition can be formed and the layers could be deposited using different techniques. In embodiment, the thickest layer is deposited using electro or electroless chemical deposition

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others.

In yet another aspect, a method for fabricating a light emitting diode, includes forming a multi-layer epitaxial structure over a sapphire substrate, wherein the multi-layer epitaxial structure comprises a multi-quantum well (MQW) layer; coating a metal plating layer above the multi-layer epitaxial structure; removing the sapphire substrate; and providing an n-electrode on the surface of the multi-layer structure and a p-electrode on the metal plating layer and forming heat removal device(s) thereon.

Implementations of the above aspect may include one or more of the following. The metal plating layer can be formed by electroplating. The metal plating layer can also be formed using electroless-plating and by protecting the sapphire substrate with a polyimide layer. The sapphire substrate can be removed using laser lift-off (LLO) technique. The multilayer epitaxial layer can be a reflective metal layer coupled to the metal plating layer; a passivation layer coupled to the reflective metal layer; a p-GaN layer coupled to the passivation layer; a n-GaN layer coupled to the MQW layer; an n-electrode coupled to the n-GaN layer; and a p-electrode coupled to the metal plating layer.

In another aspect, a vertical device structure for a light-emitting device (LED) can be fabricated by forming a multi-layer epitaxial structure over a sapphire substrate, wherein the multi-layer epitaxial structure comprises an multi-quantum well (MQW) active layer; coating a metal plating layer above the multi-layer epitaxial structure; removing the sapphire substrate; and providing an n-electrode on the surface of the multi-layer structure and a p-electrode on the metal plating layer.

The metal layer can be single or multi-layered. In case that the metal layer is a multi-layer, a plurality of metal layers with different composition can be formed and the layers could be deposited using different techniques. In embodiment, the thickest layer is deposited using electro or electroless chemical deposition In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others.

In yet another aspect, a vertical LED includes a multilayer epitaxial layer formed above a temporary substrate; a metal plating layer formed above the multilayer epitaxial layer, wherein the temporary substrate is removed using laser-lift-off after forming the metal plating layer.

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others.

In another aspect, a vertical light emitting diode includes a metal plating layer; a reflective metal layer coupled to the metal plating layer; a passivation layer coupled to the reflective metal layer; a p-GaN layer coupled to the passivation layer; a multi-quantum well (MQW) layer coupled to the p-GaN layer; a n-GaN layer coupled to the MQW layer; g. an n-electrode coupled to the n-GaN layer; and a p-electrode coupled to the metal plating layer and forming heat removal fins thereon.

In one embodiment, Ag/Cr is used as a mirror layer, Ni is used as a barrier for Gold as a seed layer for copper plating which is used as the bulk substrate. The mirror layer (Ag, Al, Ti, Cr for example) is deposited and then a barrier layer such as TiN, TaN, TiWN, TiW stuffed with Oxygen is formed above the mirror layer before electro or electroless chemical deposition of a metal such as Ni or Cu. For electrochemical deposition of copper, a seed layer is deposited using CVD, MOCVD, PVD, ALD, or evaporation process with Au, Cu or Ni, among others.

The invention can be implemented to realize one or more of the following advantages, alone or in various possible combinations. The fins provide efficient heat sinks that minimize stress created at the heat sink-integrated circuit junction when the integrated circuit heats up and cools down during use. Since the LED integrated circuit is physically bonded to the heat removing fins, the integrated circuit itself, the electrical connections expand and contract at the same rates and at the same coefficient of thermal expansion. The system provides an optimum contact between the integrated circuit and the heat sink to maximize the conduction of heat away from the LED integrated circuit. In addition to removing heat, the fins provide structural support to the LED. The result is a lightweight, compact heat removing technique that also can provide structural support to the LED. Heat can be removed from the LED without the use of fans. Heat can be removed from the LED with little noise or in silence. Heat can be removed without the vibrations, electromagnetic noise, or mechanical resonance caused by fans. The variability of magnetic and electric fields in the electronics with the LED can be reduced. Maintenance issues created by the use of fans can be reduced or eliminated. Mechanical fatigue of components can be reduced. The circulation of air into the electronics is not necessary. The electronics with the LED can be sealed. The electronics can exclude moisture, and can be operated in moist or chemically adverse environments. Maintenance issues created by entry of dust, ions, debris, airborne chemicals, and contaminants can be minimized or eliminated. The electronics that deploy the LED can be protected from external electric, magnetic and electromagnetic fields. Performance of the system can be improved. The lifespan and reliability of the system can be improved.

Additionally, current can spread out uniformly from n-electrode to p-electrode, thus increasing LED performance. Moreover, the metal substrate can dissipate more heat than the sapphire substrate, so more current can be used to drive the LED. The resulting LED can replace the conventional LED at a smaller size. For the same LED size, the light output from vertical LED is significantly higher than the conventional LED for the same drive current.

The thermoelectric cooler removes the need to restrict the operation of LED devices to lower power levels, lower data rates, and/or lower operating frequencies. The embedded thermoelectric cooler provides heat transfer capabilities with excellent size, location, and thermal capabilities. The speed and power capabilities of the LED device and other electronic components can be increased. This is done without requiring a heat sink typically used as a conductor to dissipate excessive heat to prevent the IC device, and other heat generating electronic components, from overheating. The thermoelectric cooler also avoids the need for filling the thermal gap with grease to provide the thermal conduction path between the heat sink and the LED device to improve heat transfer and dissipation.

Furthermore, the embedded thermoelectric cooler does not require a phase change when introduced to and removed from the heat sink and does not require any pressure to be applied on the IC package. The application of high pressure during the mounting of the heat sink negatively affects the reliability of the IC package and the thermal interface, resulting in lack of re-workability of the thermal material, higher resistance, and decreased reliability.

One implementation includes all of the above described advantages.

### BRIEF DESCRIPTION OF THE DRAWINGS

To better understand the other features, technical concepts and objects of the present invention, one may clearly read the description of the following preferred embodiments and the accompanying drawings, in which:

FIGS. 1-8 show operations in an exemplary process to fabricate various embodiments of LEDs with improved heat dissipation.

FIGS. 9A-9C show exemplary processes for depositing thermoelectric coolers on the LED.

### DESCRIPTION

In reading the detailed description, the accompanying drawings may be referenced at the same time and considered as part of the detailed description. In the description, the reference numerals given for the inventive device structure will be also used in the recitation of the steps of the inventive manufacturing method.

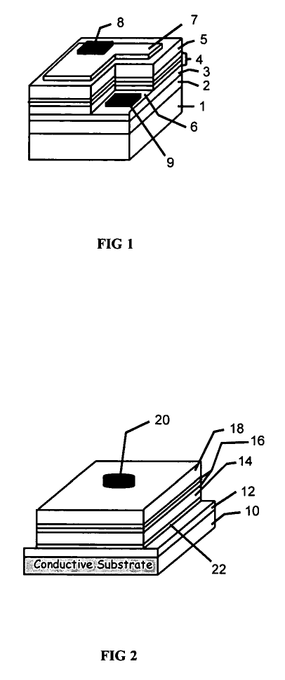

Referring to FIGS. 1 to 9, a manufacturing method for an embodiment of a vertical LED with heat dissipation fins is illustrated therein. The process described below is for one embodiment with InGaN LEDs initially grown on sapphire. Electroplating is then used to deposit a thick contact for electrical and thermal conduction for the resulting LED device. Electroplating is used in lieu of wafer bonding. The process can be applied to any optoelectronic device where bonding was used to attach the epilayer to a new host substrate for improvement of optical, electrical and thermal properties.

FIG. 1 shows an LED with a deposited thermoelectric cooler as a heat removing element as discussed in more detail below. As shown therein, the substrate with the thermoelectric cooler is denoted as 1. The substrate 1 can be mostly sapphire. Over the substrate 1, a buffer layer 2 is formed to reduce the lattice mismatch between substrate 1 and GaN. The buffer layer 2 can be epitaxially grown on the substrate 1 and can be AlN, GaN, AlGaN or AlInGaN. Next, an n-GaN based layer 3, a multi-quantum well (MQW) layer 4, and a p-GaN layer 5 are formed in sequence. An etching method is employed to form an exposing region 6 on the n-GaN based layer 3. An electrical conductive semi-transparent coating is provided above the p-GaN layer 5. Finally, the n-electrode 9 and p-electrode 8 are formed on selected electrode areas. The n-electrode 9 is needed on the same side of device as p-electrode to inject electrons and holes into the MQW active layer 4, respectively. The radiative recombination of holes and electrons in the layer 4 emits light. However, limitations of this conventional LED structure include: (1) Semi-transparent contact on p-layer 5 is not 100% transparent and can block the light emitted from layer 4; (2) current spreading from n-electrode to p-electrode is not uniform due to position of electrodes; and (3) heat is accumulated during device operation since sapphire is a thermal and electrical insulator.

To increase available lighting area, vertical LEDs can be used. As shown in FIG. 2, a vertical LED has a substrate 10 (typically silicon, GaAs or Ge) with a deposited thermoelectric cooler therein. Over the substrate 10, a transition metal multi-layer 12, a p-GaN layer 14, an MQW layer 16, a n-GaN layer 18 are then formed. The n-electrode 20 and the p-electrode 22 are then formed on selected areas as electrodes.

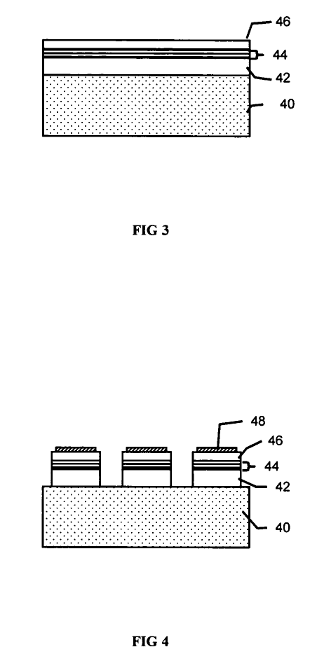

FIGS. 3-8 show another embodiment of a vertical LED. As shown in FIG. 3, the LED has a multi-layer epitaxial structure of an exemplary InGaN LED on a carrier 40, which can be a sapphire substrate in one embodiment. The multi-layer epitaxial structure formed above the sapphire substrate 40 includes an n-GaN based layer 42, an MQW active layer 44 and a contact layer 46. The n-GaN based layer 42 may be a doped n-GaN based layer, such as one doped with Si for electricity conduction, having a thickness of about 4 microns, for example.

The MQW active layer 44 can be an InGaN/GaN (or AlGaN/GaN) MQW active layer. Once an electric power is fed between the n-GaN based layer 42 and the contact layer 46, the MQW active layer 44 may be excited and thus generates a light. The produced light can have a wavelength between 250 nm to 600 nm. The p-layer can be a p⁺-GaN based layer, such as a p⁺-GaN, a p⁺-InGaN or a p⁺-AlInGaN layer and the thickness thereof may be between 0.01-0.5 microns.

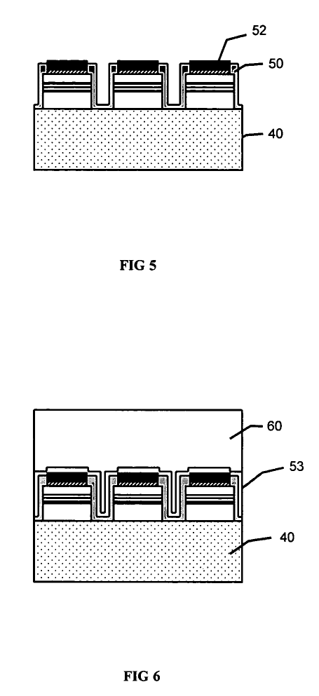

Next, as shown in FIG. 4, a mesa definition process is performed and p-type transparent contacts 48 are formed above the contact layer 46. The transparent contacts 48 can be ITO, Ni/Au, among others. In addition, direct reflected Ag deposition as a metal contact could be also formed. Individual LED devices are formed following mesa definition. Ion coupled plasma etching is used to etch GaN into separate devices.

Next, as shown in FIG. 5, a passivation layer 50 is deposited and reflective metal deposition is performed to form a reflective metal 52 such as Al, Ag, and Cr, among others, in a window etched above the passivation layer 50. The passivation layer 50 is non-conductive. The reflective metal 52 forms a mirror surface.

FIG. 6 shows that a thin metal layer 53 (Cr, Cr/Au, Ni/Au, Ti/Au among others) is coated over the structure to serve as a electrode in the electroplating process. However the coating operation is not needed if an electroless process, sputtering or magneto-sputtering process is used in lieu of electroplating. A metal substrate layer 60 is coated thereon.

Turning now to FIG. 6, the multi-layer epitaxial structure is coated with a metal plating layer 60 using techniques such as electroplating and electroless-plating. With electroless-plating, the sapphire substrate 40 is protected using a polyimide layer or a coating that can be easily removed without damaging the sapphire or the electroless plated metal of a relatively thick metal such as Ni or Cu, among others.

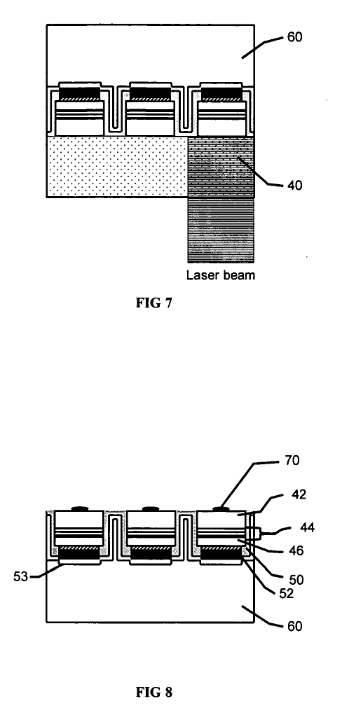

Next, the sapphire substrate 40 is removed. In one embodiment shown in FIG. 7, a laser lift-off (LLO) operation is applied to the sapphire substrate 40. Sapphire substrate removal using laser lift-off is known, reference U.S. Pat. No. 6,071,795 to Cheung et al., entitled, “Separation of Thin Films From Transparent Substrates By Selective Optical Processing,” issued on Jun. 6, 2000, and Kelly et al. “Optical process for liftoff of group III-nitride films”, Physica Status Solidi (a) vol. 159, 1997, pp. R3-R4). Furthermore, highly advantageous methods of fabricating GaN semiconductor layers on sapphire (or other insulating and/or hard) substrates are taught in U.S. patent application Ser. No. 10/118,317 entitled “A Method of Fabricating Vertical Devices Using a Metal Support 5 Film” and filed on Apr. 9, 2002 by Myung Cheol Yoo, and in U.S. patent application Ser. No. 10/118,316 entitled “Method of Fabricating Vertical Structure” and filed on Apr. 9, 2002 by Lee et al. Additionally, a method of etching GaN and sapphire (and other materials) is taught in U.S. patent application Ser. No. 10/118,318 entitled “A Method to Improve Light Output of GaN-Based Light Emitting Diodes” and filed on Apr. 9, 2002 by Yeom et al., all of which are hereby incorporated by reference as if fully set forth herein.

As shown in FIG. 8, an n-type electrode 70 is patterned on the top of n-GaN layer 42 to complete the vertical LED. A p-electrode and an n-electrode are disposed on the multi-layer epitaxial structure to complete the formation of a vertical GaN-based LED.

The thin metal layer or film 53 is provided as a seeding material purpose of the metal plating layer 60. The thin metal film 53 may be the same or different material with the metal plating layer 60 as long as the metal plating layer 60 may be plated on top of the film 53 using electrochemical deposition or electroless chemical deposition.

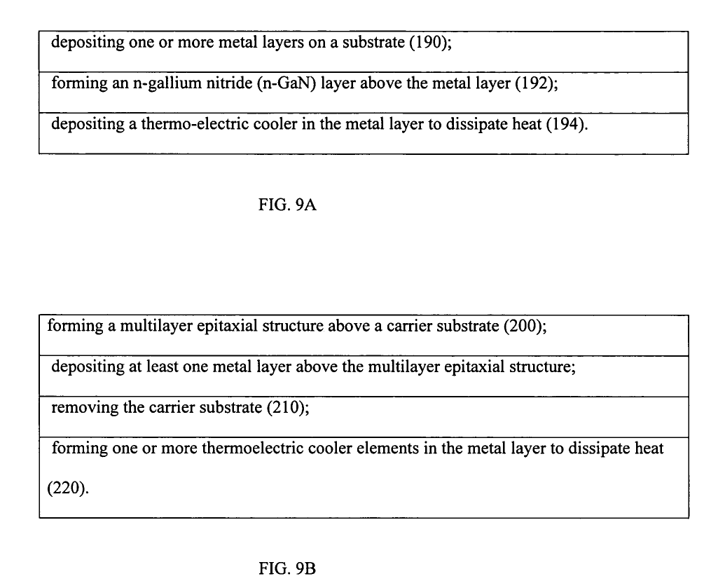

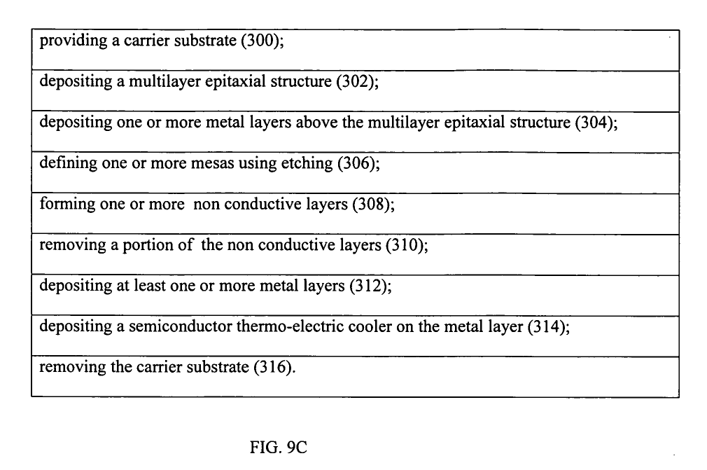

FIG. 9A shows an exemplary process for cooling an LED during operation. The process includes depositing one or more metal layers on a substrate (190); forming an n-gallium nitride (n-GaN) layer above the metal layer (192); and depositing a thermo-electric cooler in the metal layer to dissipate heat (194).

As shown in FIG. 9B, a process for fabricating a device with heat removal feature includes forming a multilayer epitaxial structure above a carrier substrate (200); depositing at least one metal layer above the multilayer epitaxial structure; removing the carrier substrate (210) and forming one or more thermoelectric cooler elements in the metal layer to dissipate heat (220).

As shown in FIG. 9C, a third embodiment of the process includes providing a carrier substrate (300); depositing a multilayer epitaxial structure (302); depositing one or more metal layers above the multilayer epitaxial structure (304); defining one or more mesas using etching (306); forming one or more non conductive layers (308); removing a portion of the non conductive layers (310); depositing at least one or more metal layers (312); depositing a semiconductor thermo-electric cooler on the metal layer (314); and removing the carrier substrate (316).

In the process of FIG. 9A-9C, a heat dissipating element such as a thermo-electric cooler is formed on the metal plating layer 60. Thermoelectric devices may be described as essentially solid state heat pumps which follow the laws of thermodynamics in the same manner as mechanical heat pumps, refrigerators, or any other apparatus used to transfer heat energy. The efficiency of a thermoelectric device is generally limited to its associated Carnot cycle efficiency reduced by a factor which is dependent upon the thermoelectric figure of merit (ZT) of materials used in fabrication of the associated thermoelectric elements. Materials used to fabricate other components such as electrical connections, hot plates and cold plates may also affect the overall efficiency of the resulting thermoelectric device. By embedding the thermoelectric cooler in the metal layer, the efficiency of the thermoelectric cooler on the LED is improved.

The thermoelectric material can be alloys of Bi₂Te₃, PbTe and BiSb, SiGe. These materials remove heat from the LED by Peltier effect, a phenomenon whereby heat is liberated or absorbed at a junction when current passes from one metal to another. A cold junction (the place where the heat source or load is located) is defined as the assembly where energy in the form of heat is absorbed when current passes from one metal to another. A hot junction (the place where the heat sink is located) is the assembly which thermally communicates with a heat exchanger and through which the heat that is liberated, when current passes from one metal to another, is transferred to the ambient environment. In one embodiment, a billet of P-type material is extruded to form a P-type extrusion. Similarly, a billet of N-type material is extruded to form an N-type extrusion. The P and N-type extrusions are sliced into wafers, the wafers are sliced into elements, and the elements are mechanically loaded into a grid or “matrix” with the desired pattern and assembled upon a plate. P-type and N-type elements are typically arranged into rectangular arrays, in order to form a thermoelectric device. P-type and N-type legs alternate in both array directions. A metallization may be applied to the P-type wafers, N-type wafers, and/or the plate, in order to arrange the P-type wafers and the N-type wafers electrically in series and thermally in parallel.

Optionally, in addition to the thermoelectric cooler, heat dissipating fins can be dry etched or wet etched on the metal plating layer 60. In another embodiment, angled fins are arrayed around the metal layer. In other embodiments, the heat sink, heat exchanger, cold plate, and the like can be formed on the metal plating layer 60. The heat sink, heat exchanger, cold plate, and the like have a high thermal conductivity to draw heat from the LED device and transfer it to ambient air.

The heat dissipation element provides a large surface area for convective dissipation of heat into the environment. The heat dissipation element can have externally projecting features shaped like fins, blades, rudders, sheets, or the like. The degree of heat dissipated by convection can be adjusted by changing the shape or size of the heat dissipation element. For example, increasing the surface area of the externally projecting features without changing their volume typically increases the degree of heat dissipated by convection. The heat can be dissipated from the heat dissipation element by passive convection, for example, due to naturally occurring air movement external to the LED. The heat also can be dissipated from the heat dissipation element by forced convection, for example, air movements created by external fans and/or coolant being pumped through conduits (e.g., tubes) thermally coupled to the heat dissipating element. The configuration of the system can be varied depending on the heat removal requirements of the encased electronic device. For example, the thermal connectors that provide conduction pathways can be made of more conductive materials, shortened, and/or have increased cross sectional area when the heat removal requirements are increased.

Convection involves heat removal by the circulation of one or more fluids, e.g., air, gas, vapor, water, oil, coolant, water ethylglycol (WEG), and the like, around, through, and/or against the LED device, heat sink, heat exchanger, cold plate, and the like. The circulating fluid draws heat from the device, heat sink, heat exchanger, cold plate, and the like, and transports the heat to ambient air.

Alternately, the fins or heat sink body may be any other type of heat sink body or device such as a block of heat conductive material, a heat pipe, a piezoelectric cooler or other heat sink known to those skilled in the art. The shape and size of a particular heat sink are based on the application in which it is used, the design of such being well-known in the art.

Heat removal and thermal control of the LED can be effected further in the design of each fin and the arrangement of the plurality of fins. For example, the width, pitch, length and twist, or skew, angle of each individual fin can be controlled to provide a variety of cooling capabilities. Similarly, the aspect ratio, number of integral fins, dimensions of the metal layer 60, and the arrangement of the plurality of integral fins can be controlled to do the same. Those skilled in the art can appreciate the myriad fin and metal layer 60 patterns that can be used to provide practically any efficacious flow.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for cooling a light emitting diode, comprising:
depositing one or more metal layers on a substrate;
forming an n-gallium nitride (n-GaN) layer above the metal layer; and
depositing a thermoelectric cooler in the metal layer to dissipate heat.

2. The method of claim 1, wherein depositing the thermoelectric cooler comprises depositing one of: Bi₂Te₃, PbTe and BiSb, SiGe, or alloys thereof.

3. The method of claim 1, comprising:
forming a multilayer epitaxial structure above a carrier substrate; and
removing the carrier substrate.

4. The method of claim 3, wherein the carrier substrate comprises sapphire.

5. The method of claim 1, wherein the depositing the metal layer comprises electro chemical deposition.

6. The method of claim 1, wherein depositing one or more metal layers comprises sputtering, physical vapor deposition (PVD), chemical vapor deposition (CVD), plasma enhanced CVD (PECVD), evaporation-ion beam deposition, electro deposition, electroless deposition, plasma spray, or ink jet deposition.

7. The method of claim 1, comprising depositing one or more metal layers using one of: PVD, evaporation-ion beam deposition, CVD, or e-beam deposition.

8. The method of claim 1, wherein the metal layer includes one of: chromium (Cr), nickel (Ni), tantalum nitride copper (TaN/Cu), molybdenum (Mo), tungsten (W) or a metal alloy.

9. The method of claim 1, wherein the depositing metal layer comprises depositing at least a metal layer followed by one or more electroless chemical depositions.

10. The method of claim 1, wherein depositing metal layer comprising applying using one of: CVD, PECVD, PVD, ALD, MOCVD, evaporation, and plasma spray.
The method of claim 1, comprising depositing one or more additional metal layers above the metal layer.

11. The method of claim 1, wherein depositing one or more metal layers comprises sputtering, physical vapor deposition (PVD), chemical vapor deposition (CVD), plasma enhanced CVD (PECVD), evaporation-ion beam deposition, electro deposition, electroless deposition, plasma spray, or ink jet deposition.

12. The method of claim 1, comprising depositing one or more metal layers using one of: PVD, evaporation-ion beam deposition, CVD, or e-beam deposition.

13. The method of claim 1, wherein one metal layer includes one of: chromium (Cr), nickel (Ni), tantalum nitride copper (TaN/Cu), molybdenum (Mo), tungsten (W) or a metal alloy.

14. The method of claim 1, wherein the LED comprises one of: a vertical LED and a planar LED.

15. A method for fabricating a light emitting diode, comprising:
providing a carrier substrate;
depositing a multilayer epitaxial structure;
depositing one or more metal layers above the multilayer epitaxial structure;
defining one or more mesas using etching;
forming one or more non conductive layers;
removing a portion of the non conductive layers;
depositing at least one or more metal layers;
depositing a semiconductor thermoelectric cooler on the metal layer; and
removing the carrier substrate.

16. An LED, comprising:
one or more metal layers on a substrate;
an n-gallium nitride (n-GaN) layer above the metal layer; and
a thermo-electric cooler in the metal layer to dissipate heat.

17. The LED of claim 16, wherein the thermo-electric cooler comprises a semiconductor structure made from one of: Bi₂Te₃, PbTe and BiSb, SiGe, or alloys thereof.

18. The LED of claim 16, wherein the thermoelectric cooler is fabricated on a wafer.

19. The LED of claim 16, comprising a heat conducting substrate coupled to the LED after LED fabrication to increase heat dissipation.

20. The LED of claim 16, wherein the LED is a vertical LED.
